(19) United States
(12) Patent Application Publication
(10) Pub. No.: US 2020/0294991 A1
(43) Pub. Date: Sep. 17, 2020

(54) BOOTSTRAP DIODE WITH LOW SUBSTRATE LEAKAGE CURRENT

(71) Applicant: Nuvoton Technology Corporation, Hsinchu Science Park (TW)

(72) Inventors: Vivek NINGARAJU, kuvempunagar (IN); Po-An CHEN, Toufen City (TW)

(21) Appl. No.: 16/694,394

(22) Filed: Nov. 25, 2019

(30) Foreign Application Priority Data
Mar. 15, 2019 (TW) 108108769

(51) Int. Cl. H01L 27/02

(52) U.S. Cl. CPC H01L 27/0255; H01L 27/0274

(57) ABSTRACT

A semiconductor device includes a diode, a metal-oxide semiconductor, and a junction field-effect transistor. The diode includes an anode node and a cathode node, wherein the anode node is coupled to a first node. The metal-oxide semiconductor includes a first source/drain terminal, a second source/drain terminal, and a first gate terminal, wherein the first source/drain terminal is coupled to the cathode node and the first gate terminal receives a first control voltage. The junction field-effect transistor includes a third source/drain terminal, a fourth source/drain terminal, and a second gate terminal, wherein the second gate terminal receives a second control voltage, the third source/drain terminal is coupled to the second source/drain terminal, and the fourth source/drain terminal is coupled to a second node.

### CROSS REFERENCE TO RELATED APPLICATIONS

This Application claims priority of Taiwan Patent Application No. 108108769, filed on Mar. 15, 2019, the entirety of which is incorporated by reference herein.

### BACKGROUND OF THE INVENTION

### Field of the Invention

The disclosure relates generally to a semiconductor device, and more particularly it relates to a bootstrap diode having no substrate leakage current.

### Description of the Related Art

Improving power efficiency has been a great concern. Off-line power converters that are capable of reducing power consumption are also becoming increasingly important. In response to changes in the consumer market, HVIC chips have gradually been adopted more widely because they have better performance and are capable of satisfying low-cost so a designer has the flexibility to achieve solutions when implementing high-performance power converters.

An example of the effects of the HVIC chip is the gate driver, which is used to drive a metal-oxide-semiconductor field-effect transistor (MOSFET) or an insulated gate bipolar transistor (IGBT), in which a bootstrap diode, a capacitor and a resistor are usually used to form a bootstrap circuit. Taking a floating voltage level of the source voltage of the MOSFET belonging to the high-side circuit as the base, a voltage level of the HVIC can be provided.

However, when the bootstrap diode is forward biased, there is a drawback in that there is current leaking to the semiconductor substrate. In addition, a normal bootstrap diode cannot sustain high voltages. When the bootstrap diode is reverse-biased by voltage that is too high, the bootstrap diode would break down and be turned ON, causing the bootstrap diode to fail at its sole purpose of conducting unidirectionally. Therefore, the leakage of the bootstrap diode should be eliminated and the voltage level at which the bootstrap diode is sustainable should be improved.

### BRIEF SUMMARY OF THE INVENTION

In an embodiment, a semiconductor device comprises: a diode, a metal-oxide semiconductor, and a junction field-effect transistor. The diode comprises an anode node and a cathode node, wherein the anode node is coupled to a first node. The metal-oxide semiconductor comprises a first source/drain terminal, a second source/drain terminal, and a first gate terminal, wherein the first source/drain terminal is coupled to the cathode node and the first gate terminal receives a first control voltage. The junction field-effect transistor comprises a third source/drain terminal, a fourth source/drain terminal, and a second gate terminal, wherein the second gate terminal receives a second control voltage, the third source/drain terminal is coupled to the second source/drain terminal, and the fourth source/drain terminal is coupled to a second node.

According to an embodiment of the invention, the second gate terminal is coupled to a ground.

According to an embodiment of the invention, when a voltage of the first node exceeds a voltage of the second node, the metal-oxide semiconductor is turned ON according to the first control voltage, and the semiconductor device provides the voltage of the first node to the second node.

According to an embodiment of the invention, when the voltage of the first node does not exceed the voltage of the second node, the metal-oxide semiconductor is turned OFF according to the first control voltage, and the semiconductor device electrically isolates the first node from the second node.

According to an embodiment of the invention, the semiconductor device further comprises a semiconductor substrate, a buried layer, a first well, a second well, and a third well. The semiconductor substrate has a first conductivity type. The buried layer has a second conductivity type. The first well has the second conductivity type and is formed on the buried layer. The second well has the second conductivity type and is formed on the buried layer. The third well has the first conductivity type, which is formed on the buried layer and deposited between the first well and the second well.

According to an embodiment of the invention, the semiconductor device further comprises a first doping region, a second doping region, a third doping region, and a fourth doping region. The first doping region has the second conductivity type and is formed in the first well. The second doping region has the second conductivity type and is formed in the second well, wherein the second doping region is electrically coupled to the first doping region. The third doping region has the second conductivity type and is formed in the third well. The fourth doping region has the first conductivity type and is formed in the third well.

According to an embodiment of the invention, the third doping region, the fourth doping region, and the third well form the diode.

According to an embodiment of the invention, the third doping region forms the cathode node of the diode, and the first doping region, the second doping region, and the fourth doping region form the anode node of the diode.

According to an embodiment of the invention, the first well, the second well, and the buried layer are configured to lower a leakage current that flows from the fourth doping region to the semiconductor substrate through the third well.

According to an embodiment of the invention, the semiconductor device further comprises a fourth well and a fifth doping region. The fourth well has the first conductivity type and is formed in the semiconductor substrate. The fifth doping region has the second conductivity type and is formed in the fourth well.

According to an embodiment of the invention, the semiconductor device further comprises a fifth well, a sixth doping region, and a gate structure. The fifth well has the second conductivity type and is formed in the fourth well. The sixth doping region has the second conductivity type and is formed in the fifth well. The gate structure is formed in the fourth well and is deposited between the fifth doping region and the sixth doping region and on the fifth well.

According to an embodiment of the invention, the gate structure, the fifth doping region, and the sixth doping region respectively form the first gate terminal, the first source/drain terminal, and the second source/drain terminal of the metal-oxide semiconductor.

According to an embodiment of the invention, the fifth doping region is electrically coupled to the third doping region and the gate structure receives the first control voltage.

According to an embodiment of the invention, the semiconductor device further comprises a sixth well, a seventh doping region, and an eighth doping region. The sixth well has the second conductivity type and is formed in the semiconductor substrate. The seventh doping region has the second conductivity type and is formed in the sixth well. The eighth doping region has the second conductivity type and is formed in the sixth well.

According to an embodiment of the invention, the semiconductor device further comprises a seventh well and a ninth doping region. The seventh well has the first conductivity type, which is formed in the sixth well and deposited between the seventh doping region and the eighth doping region. The ninth doping region has the first conductivity type and is formed in the seventh well.

According to an embodiment of the invention, the seventh doping region, the eighth doping region, and the ninth doping region form the junction field-effect transistor, wherein the seventh doping region forms the third source/drain terminal, the eighth doping region forms the fourth source/drain terminal, and the ninth doping region forms the second gate terminal.

According to an embodiment of the invention, the seventh doping region is electrically coupled to the sixth doping region, the eighth doping region is electrically coupled to the second node, and the ninth doping region receives the second control voltage.

According to an embodiment of the invention, there is a predetermined distance between the eighth doping region and the ninth doping region, wherein the predetermined distance determines a maximum voltage of the second node.

According to an embodiment of the invention, the first doping region, the fourth doping region, the third doping region, the second doping region, the fifth doping region, the sixth doping region, the seventh doping region, the ninth doping region, and the eighth doping region are formed as a concentric structure.

According to an embodiment of the invention, the first conductivity type is P-type and the second conductivity type is N-type.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic diagram of a semiconductor device in accordance with an embodiment of the invention;

FIG. 2 is a block diagram of a power driving circuit in accordance with an embodiment of the invention;

FIG. 3 is a cross-sectional view of a semiconductor device in accordance with an embodiment of the invention; and

FIG. 4 is a top view of a semiconductor device in accordance with an embodiment of the invention.

### DETAILED DESCRIPTION OF THE INVENTION

The semiconductor device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

This description of the exemplary embodiments is intended to be read in connection with the accompanying drawings, which are to be considered part of the entire written description. The drawings are not drawn to scale. In addition, structures and devices are shown schematically in order to simplify the drawing.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

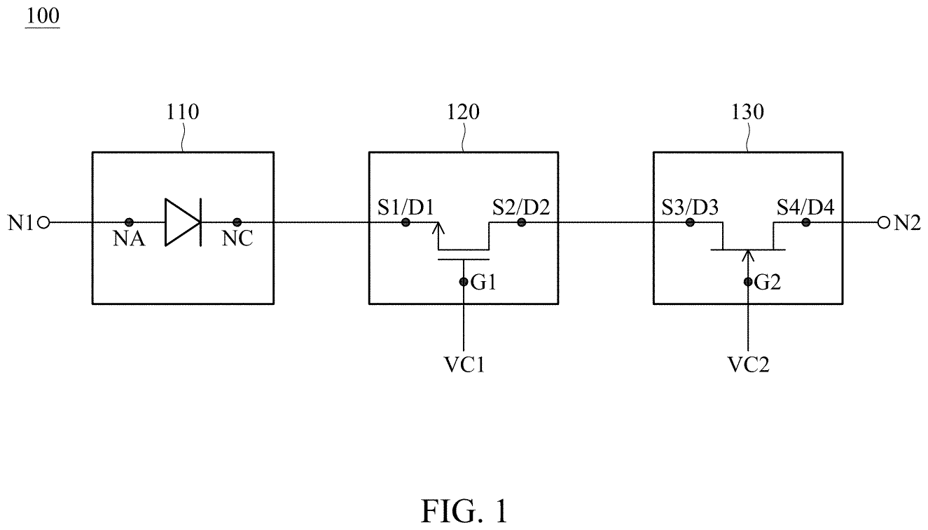

FIG. 1 is a schematic diagram of a semiconductor device in accordance with an embodiment of the invention. As shown in FIG. 1, the semiconductor device 100 includes a diode 110, a metal-oxide semiconductor (MOS) 120, and a junction field-effect transistor (JFET) 130. According to an embodiment of the invention, the semiconductor device 100 is configured as a bootstrap diode having no substrate leakage and being sustainable (i.e., when the voltage of the second node N2 far greater than the voltage of the first node N1), which will be described in the following paragraphs.

As shown in FIG. 1, the semiconductor device 100 further includes a first node N1 and a second node N2. According to an embodiment of the invention, when the voltage of the first node N1 exceeds that of the second node N2, the semiconductor device 100 provides the voltage of the first node N1 to the second node N2. According to another embodiment of the invention, when the voltage of the second node N2 exceeds that of the first node N1, the semiconductor device 100 is configured to electrically isolate the first node N1 from the second node N2.

The diode 110 includes an anode node NA and a cathode node NC, in which the anode node NA is electrically coupled to the first node N1. The MOS 120 includes a first source/drain terminal S1/D1, a second source/drain terminal S2/D2, and a first gate terminal G1, in which the first source/drain terminal S1/D1 is electrically coupled to the cathode node NC and the first gate terminal G1 receives the first control voltage VC1. According to an embodiment of the invention, as shown in FIG. 1, the MOS 120 is an N-type MOS.

The JFET 130 includes a third source/drain terminal S3/D3, a fourth source/drain terminal S4/D4, and a second gate terminal G2, in which the second gate terminal G2 receives a second control voltage VC2, the third source/drain terminal S3/D3 is coupled to the second source/drain terminal S2/D2, and the fourth source/drain terminal S4/D4 is coupled to the second node N2. According to an embodiment of the invention, as shown in FIG. 1, the JFET 130 is an N-type JFET.

According to an embodiment of the invention, when the voltage of the first node N1 exceeds that of the second node N2, the MOS 120 is turned ON according to the first control voltage VC1, and the second control signal VC2 is in the ground level of the ground.

According to another embodiment of the invention, when the voltage of the second node N2 exceeds that of the first node N1, the MOS 120 is turned OFF according to the first control voltage VC1 and the second control voltage VC2 is in the ground level. Meanwhile, the semiconductor device 100 electrically isolates the first node N1 from the second node N2.

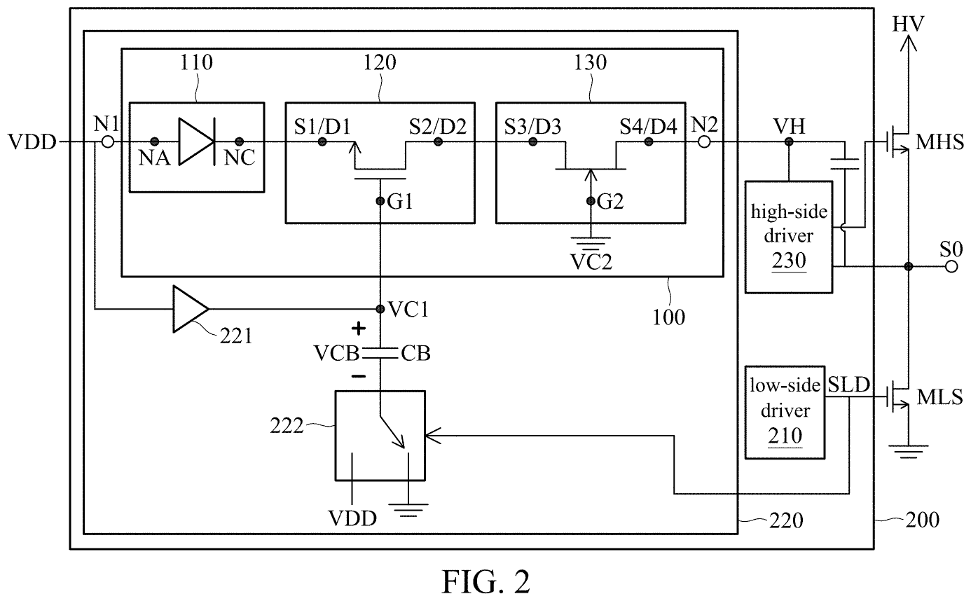

FIG. 2 is a block diagram of a power driving circuit in accordance with an embodiment of the invention. As shown in FIG. 2, the power driving circuit 200 is configured to alternatively turn ON the high-side transistor MHS and the low-side transistor MLS to generate an output signal SO, in which the supply voltage VDD is less than the external voltage HV. The power driving circuit 200 includes a low-side driver 210, a bootstrap circuit 220, and a high-side driver 230.

The low-side driver 210 generates a low-side driving signal SLD such that the low-side transistor MLS is turned ON according to the signal SLD generated by the low-side driver 210, and the high-side transistor MHS is turned OFF. The bootstrap circuit 220 includes the semiconductor device 100, a driver 221, a selector 222, and a bootstrap capacitor CB, in which the semiconductor device 100 is configured as a bootstrap diode, and the second control voltage VC2 is in the ground level, i.e., the second gate terminal G2 is coupled to the ground.

According to an embodiment of the invention, when the low-side transistor MLS is turned OFF according to the signal generated by the low-side driver 210, the selector 222 couples the bootstrap capacitor CB to the ground according to the low-side driving signal SLD. The driver 221 provides the supply voltage VDD to the first gate terminal G1 of the MOS 120, such that the first control voltage VC1 is equal to the supply voltage VDD to turn OFF the MOS 120 and the voltage VCB across the bootstrap capacitor CB is the supply voltage VDD.

According to another embodiment of the invention, when the low-side transistor MLS is turned ON according to the low-side driving signal SLD and the high-side transistor MHS is turned OFF, the selector 222 couples the bootstrap capacitor CB to the supply voltage VDD according to the low-side driving signal SLD, and the high-side driver 230 stops boosting the high-side voltage VH to the external voltage HV.

In addition, since the voltage VCB across the bootstrap capacitor CB is the supply voltage VDD and another terminal of the bootstrap capacitor CB is coupled to the supply voltage VDD through the selector 222, the first control voltage VC1 is thus boosted to about 2-fold of the supply voltage VDD for turning ON the MOS 120, such that the semiconductor device 110 provides the supply voltage VDD to the second node N2 as the high-side voltage VH.

Therefore, when the semiconductor 100 is turned ON, the semiconductor 100 provides the voltage of the first node N1 to the second node N2 according to the first control voltage VC1.

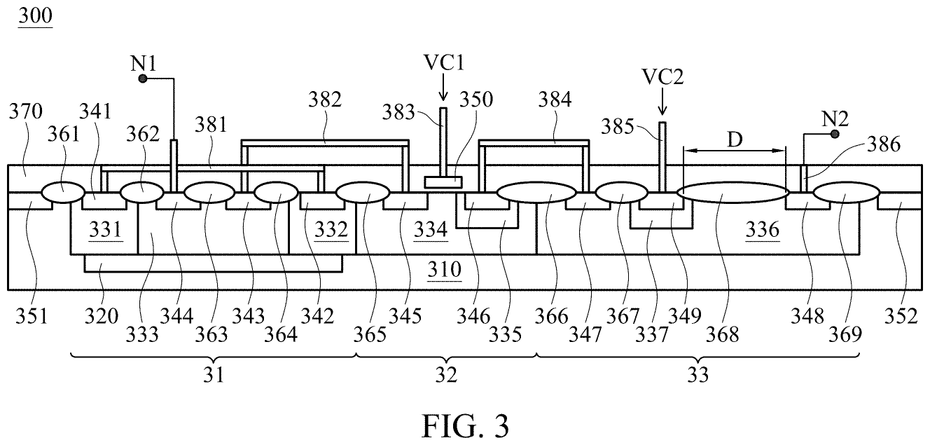

FIG. 3 is a cross-sectional view of a semiconductor device in accordance with an embodiment of the invention. As shown in FIG. 3, the semiconductor device 300 includes a semiconductor substrate 310, a buried layer 320, a first well 331, a second well 332, a third well 333, a fourth well 334, a fifth well 335, a sixth well 336, and a seventh well 337.

The semiconductor substrate 310 has a first conductivity type. According to an embodiment of the invention, the semiconductor substrate 310 is a silicon substrate. According to other embodiments of the invention, the semiconductor substrate 310 may be a light-doping semiconductor substrate with a first conductivity type.

The buried layer 320 is formed in the semiconductor substrate 310 and has a second conductivity type. According to an embodiment of the invention, the first conductivity type is P-type, and the second conductivity type is N-type. The way that the buried layer 320 is formed is not limited in the invention. According to an embodiment of the invention, the buried layer 320 may be formed by ion implantation. For example, the area that is attempted to form the buried layer 320 is implanted by phosphorus or arsenic ions for forming the N-type buried layer 320.

The first well 331 and the second well 332 is formed in the semiconductor substrate 310 and on the buried layer 320, which have the second conductivity type. In other words, the first well 331, the second well 332, and the buried layer 320 have the same conductivity type which is different from that of the semiconductor substrate 310. According to an embodiment of the invention, the first well 331 is electrically connected to the second well 332 through the buried layer 320. According to an embodiment of the invention, the first well 331 and the second well 332 are high-voltage wells.

The third well 333 is formed on the buried layer 320 and between the first well 331 and the second well 332, which has the first conductivity type. According to an embodiment of the invention, the third well 333 may be also formed by the steps of ion implantation. For example, the area that is attempted to form the third well 333 is implanted by boron or indium ions for forming the third well 333. In the embodiment, the doping concentration of the third well 333 is higher than that of the semiconductor substrate 310. According to some embodiments of the invention, the third well 333 is a high-voltage well.

The fourth well 334 is formed in the semiconductor substrate 310 and adjacent to the second well 332, which has the first conductivity type. As shown in FIG. 3, the third well 333 and the fourth well 334 are formed on both sides of the second well 33. According to an embodiment of the invention, the fourth well 334 may be formed by the steps of ion implantation. For example, the area that would like to form the fourth well 334 is implanted by boron or indium ions for forming the fourth well 334. In the embodiment, the doping concentration of the fourth well 334 is higher than that of the semiconductor substrate 310. According to some embodiments of the invention, the fourth well 334 is a high-voltage well.

The fifth well 335 is formed in the fourth well 334 and has the second conductivity type. The sixth well 336 is formed in the semiconductor substrate 310 and has the second conductivity type. The seventh well 337 is formed in the sixth well 336 and has the first conductivity type. In the embodiment, the doping concentration of the fourth well 334 is higher than that of the semiconductor substrate 310.

According to an embodiment of the invention, the semiconductor device 300 further includes a first doping region 341, a second doping region 342, a third doping region 343, a fourth doping region 344, a fifth doping region 345, a sixth doping region 346, a seventh doping region 347, an eighth doping region 348, a ninth doping region 349, and a gate structure 350.

The first doping region 341 is formed in the first well 331 and has the second conductivity type. According to an embodiment of the invention, the doping concentration of the first doping region 341 is higher than that of the first well 331. The second doping region 342 is formed in the second well 332 and has the second conductivity type. According to an embodiment of the invention, the doping concentration of the second doping region 342 is higher than that of the second well 332.

The third doping region 343 is formed in the third well 333 and has the second conductivity type. The fourth doping region 344 is formed in the third well 333 and has the first conductivity type. According to an embodiment of the invention, the doping concentration of the fourth doping region 344 is higher than that of the third well 333. According to some embodiments of the invention, the fourth doping region 344 is deposited between the first doping region 341 and the third doping region 343. According to other embodiments of the invention, the positions of the third doping region 343 and the fourth doping region 344 can be interchanged.

The fifth doping region 345 is formed in the fourth well 334 and has the second conductivity type. The sixth doping region 346 is formed in the fifth well 335 and has the second conductivity type. According to an embodiment of the invention, the doping concentration of the sixth doping region 346 is higher than that of the fifth well 335. The gate structure 350 is formed on the fourth well 334 and the fifth well 335 and deposited between the fifth doping region 345 and the sixth doping region 346.

The seventh doping region 347 and the eighth doping region 348 are formed in the sixth well 336, which have the second conductivity type. In the embodiment shown in FIG. 3, the seventh doping region 347 and the eighth doping region 348 are deposited on both sides of the seven well 337. According to an embodiment of the invention, the doping concentrations of the seventh doping region 347 and the eighth doping region 348 are higher than that of the sixth well 336.

The ninth doping region 349 is formed in the seventh well 337 and has the first conductivity type. According to an embodiment of the invention, the doping concentration of ninth doping region 349 is higher than that of the seventh well 337. According to an embodiment of the invention, the eighth doping region 348 is deposited apart from the ninth doping region 349 with a predetermined distance D.

According to an embodiment of the invention, the semiconductor device 300 further includes a tenth doping region 351 and an eleventh doping region 352. The tenth doping region 351 and the eleventh doping region 352 are formed in the semiconductor substrate 310 and have the first conductivity type, in which the doping concentrations of the tenth doping region 351 and the eleventh doping region 352 are higher than that of the semiconductor substrate 310. According to an embodiment of the invention, the tenth doping region 351 and the eleventh doping region 352 couple the semiconductor substrate 310 to the low voltage level.

According to an embodiment of the invention, the semiconductor device 300 further includes a first isolation structure 361, a second isolation structure 362, a third isolation structure 363, a fourth isolation structure 364, a fifth isolation structure 365, a sixth isolation structure 366, a seventh isolation structure 367, an eighth isolation structure 368, and a ninth isolation structure 369.

The first isolation structure 361 is deposited between the first doping region 341 and the tenth doping region 351, which is configured to isolate the first doping region 341 from the tenth doping region 351. As shown in FIG. 3, the first isolation structure 361 is directly contacted with the first doping region 341 and the tenth doping region 351, but the invention is not intended to be limited thereto. According to other embodiments of the invention, the first isolation structure 361 is not contacted with at least one of the first doping region 341 and the tenth doping region 351.

The second isolation structure 362 is deposited between the first doping region 341 and the fourth doping region 344, which is configured to isolate the first doping region 341 from the fourth doping region 344. As shown in FIG. 3, the second isolation structure 362 is directly contacted with the first doping region 341 and the fourth doping region 344, but the invention is not intended to be limited thereto. According to other embodiments of the invention, the second isolation structure 362 is not contacted with at least one of the first doping region 341 and the fourth doping region 344.

The third isolation structure 363 is deposited between the third doping region 343 and the fourth doping region 344, which is configured to isolate the third doping region 343 from the fourth doping region 344. As shown in FIG. 3, the third isolation structure 363 is directly contacted with the third doping region 343 and the fourth doping region 344, but the invention is not intended to be limited thereto. According to other embodiments of the invention, the third isolation structure 363 is not contacted with at least one of the third doping region 343 and the fourth doping region 344.

The fourth isolation structure 364 is deposited between the second doping region 342 and the third doping region 343, which is configured to isolate the second doping region 342 and the third doping region 343. As shown in FIG. 3, the fourth isolation structure 364 is directly contacted with the second doping region 342 and the third doping region 343, but the invention is not intended to be limited thereto. According to other embodiments of the invention, the fourth isolation structure 364 is not contacted with at least one of the second doping region 342 and the third doping region 343.

The fifth isolation structure 365 is deposited between the second doping region 342 and the fifth doping region 345, which is configured to isolate the second doping region 342 and the fifth doping region 345. As shown in FIG. 3, the fifth isolation structure 365 is directly contacted with the second doping region 342 and the fifth doping region 345, but the invention is not intended to be limited thereto. According to other embodiments of the invention, the fifth isolation structure 365 is not contacted with at least one of the second doping region 342 and the fifth doping region 345.

The sixth isolation structure 366 is deposited between the sixth doping region 346 and the seventh doping region 347, which is configured to isolate the sixth doping region 346 and the seventh doping region 347. As shown in FIG. 3, the sixth isolation structure 366 is directly contacted with the sixth doping region 346 and the seventh doping region 347, but the invention is not intended to be limited thereto. According to other embodiments of the invention, the sixth isolation structure 366 is not contacted with at least one of the sixth doping region 346 and the seventh doping region 347.

The seventh isolation structure 367 is deposited between the seventh doping region 347 and the ninth doping region 349, which is configured to isolate the seventh doping region 347 and the ninth doping region 349. As shown in FIG. 3, the seventh isolation structure 367 is directly contacted with the seventh doping region 347 and the ninth doping region 349, but the invention is not intended to be limited thereto. According to other embodiments of the invention, the seventh isolation structure 367 is not contacted with at least one of the seventh doping region 347 and the ninth doping region 349.

The eighth isolation structure 368 is deposited between the eighth doping region 348 and the ninth doping region 349, which is configured to isolate the eighth doping region 348 and the ninth doping region 349. As shown in FIG. 3, the eighth isolation structure 368 is directly contacted with the eighth doping region 348 and the ninth doping region 349, but the invention is not intended to be limited thereto. According to other embodiments of the invention, the eighth isolation structure 368 is not contacted with at least one of the eighth doping region 348 and the ninth doping region 349.

The ninth isolation structure 369 is deposited between the eighth doping region 348 and the eleventh doping region 352, which is configured to isolate the eighth doping region 348 and the eleventh doping region 352. As shown in FIG. 3, the ninth isolation structure 369 is directly contacted with the eighth doping region 348 and the eleventh doping region 352, but the invention is not intended to be limited thereto. According to other embodiments of the invention, the ninth isolation structure 369 is not contacted with at least one of the eighth doping region 348 and the eleventh doping region 352.

According to other embodiments of the invention, the semiconductor device 300 further includes an insulating layer 370, a first interconnect structure 381, a second interconnect structure 382, a third interconnect structure 383, a fourth interconnect structure 384, a fifth interconnect structure 385, and a sixth interconnect structure 386. The insulating layer is formed on the semiconductor substrate 310 and covered the first doping region 341, the second doping region 342, the third doping region 343, the fourth doping region 344, the fifth doping region 345, the sixth doping region 346, the seventh doping region 347, the eighth doping region 348, the ninth doping region 349, the tenth doping region 351, the eleventh doping region 352, the first isolation structure 361, the second isolation structure 362, the third isolation structure 363, the fourth isolation structure 364, the fifth isolation structure 365, the sixth isolation structure 366, the seventh isolation structure 367, the eighth isolation structure 368, and the ninth isolation structure 369.

As shown in FIG. 3, the first interconnect structure 381 electrically connects the first doping region 341, the second doping region 342, and the fourth doping region 344 to the first node N1. The second interconnect structure 382 electrically connects the third doping region 343 to the fifth doping region 345. The third interconnect structure 383 provides the first control voltage VC1 to the gate structure 350.

The fourth interconnect structure 384 electrically connects the sixth doping region 346 to the seventh doping region 347. The fifth interconnect structure 385 provides the second control voltage VC2 to the ninth doping region 349. The sixth interconnect structure 386 electrically connects the eighth doping region 348 to the second node N2. According to an embodiment of the invention, the first node N1 and the second node N2 in FIG. 3 correspond to the first node N1 and the second node N2 in FIG. 1, or the first node N1 and the second node N2 in FIG. 2.

As shown in FIG. 3, the third well 333, the third doping region 343, and the fourth doping region 344 form the diode 31, the fourth well 334, the fifth well 335, the fifth doping region 345, the sixth doping region 346, and the gate structure 350 form the MOS 32, and the sixth well 336, the seventh well 337, the seventh doping region 347, the eighth doping region 348, and the ninth doping region 349 form the JFET 33.

According to an embodiment of the invention, the diode 31 in FIG. 3 corresponds to the diode 110 in FIG. 1. As shown in FIG. 3, the fourth doping region 344 corresponds to the anode node NA in FIG. 1, the third doping region 343 corresponds to the cathode node NC in FIG. 1. According to an embodiment of the invention, the buried layer 320, the first well 331, the second well 332, the first doping region 341, and the second doping region 342 are configured to lower the leakage current from the fourth doping region 344 flowing through the third well 333 to the semiconductor substrate 310.

According to an embodiment of the invention, the MOS 32 in FIG. 3 corresponds to the MOS 120 in FIG. 1. As shown in FIG. 3, the fifth doping region 345 corresponds to the first source/drain terminal S1/D1 in FIG. 1, the sixth doping region 346 corresponds to the second source/drain terminal S2/D2 in FIG. 1, and the gate structure 350 corresponds to the first gate terminal G1 in FIG. 1.

According to an embodiment of the invention, the JFET 33 in FIG. 3 corresponds to the JFET 130 in FIG. 1. As shown in FIG. 3, the seventh doping region 347 corresponds to the third source/drain terminal S3/D3 in FIG. 1, the eighth doping region 348 corresponds to the fourth source/drain terminal S4/D4 in FIG. 1, and the ninth doping region 349 corresponds to the second gate terminal G2 in FIG. 1. According to an embodiment of the invention, the predetermined distance D is configured to determine the maximum voltage that the second node N2 is sustainable. In other words, when the maximum voltage of the second node N2 should be increased, the predetermined distance D should be increased accordingly.

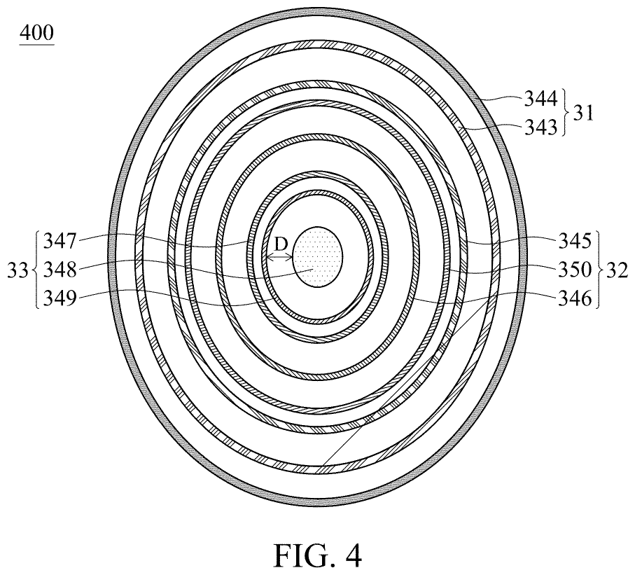

FIG. 4 is a top view of a semiconductor device in accordance with an embodiment of the invention. According to an embodiment of the invention, the semiconductor device 400 is a top view of the semiconductor device 300 in FIG. 3. In order to simplify the explanation, the semiconductor device 400 in FIG. 4 merely illustrates the third doping region 343, the fourth doping region 344, the fifth doping region 345, the sixth doping region 346, the seventh doping region 347, the eighth doping region 348, the ninth doping region 349, and the gate structure 350.

As shown in FIG. 4, the semiconductor 400 is formed by concentric circles. According to other embodiments of the invention, the semiconductor device 400 is formed by a structure of concentric circles. According to another embodiment of the invention, the semiconductor device 400 may be formed by concentric ellipses. According to some embodiments of the invention, the semiconductor device 400 may be formed by concentric polygons.

As shown in FIG. 4, the outermost layer of the semiconductor device 400 is the fourth doping region 344 and the third doping region 343, in which the third doping region 343 and the fourth doping region 344 correspond to the diode 31. According to other embodiments of the invention, the first doping region 341 in FIG. 3 may be deposited outside the fourth doping region 344, and the second doping region 342 may be deposited inside the third doping region 343. For the simplicity of explanation, the first doping region 341 and the second doping region 342 have been omitted.

As shown in FIG. 4, the fifth doping region 345, the gate structure 350, and the sixth doping region 346 are sequentially deposited inside the third doping region 343, in which the fifth doping region 345, the gate structure 350, and the sixth doping region 346 correspond to the MOS 32. According to other embodiments of the invention, the second doping region 342 in FIG. 3 may be deposited between the third doping region 343 and the fifth doping region 345.

As shown in FIG. 4, the seventh doping region 347, the ninth doping region 349, and the eighth doping region 348 are sequentially deposited inside the sixth doping region 346, in which the seventh doping region 347, the ninth doping region 349, and the eighth doping region 348 correspond to the JFET 33. According to an embodiment of the invention, when the maximum voltage of the second node N2 should be increased, the predetermined distance D should be increased accordingly such that the circuit area occupied by the semiconductor device 400 is therefore increased.

The semiconductor device 400 is illustrated for explanation, but not intended to be limited thereto.

A semiconductor device as a bootstrap diode is provided herein, which is able to effectively solve the problem of leakage current flowing to the semiconductor substrate when the bootstrap diode is forward biased so that substrate noise can be eliminated without the need for any additional masks. In addition, the second node N2 of the semiconductor device provided herein could sustain an extra high voltage. According to an embodiment of the invention, the second node N2 of the semiconductor device can sustain a voltage as high as 1000V.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a diode, comprising an anode node and a cathode node, wherein the anode node is coupled to a first node;
a metal-oxide semiconductor, comprising a first source/drain terminal, a second source/drain terminal, and a first gate terminal, wherein the first source/drain terminal is coupled to the cathode node and the first gate terminal receives a first control voltage; and
a junction field-effect transistor, comprising a third source/drain terminal, a fourth source/drain terminal, and a second gate terminal, wherein the second gate terminal receives a second control voltage, the third source/drain terminal is coupled to the second source/drain terminal, and the fourth source/drain terminal is coupled to a second node.

2. The semiconductor device of claim 1, wherein the second gate terminal is coupled to a ground.

3. The semiconductor device of claim 2, wherein when a voltage of the first node exceeds a voltage of the second node, the metal-oxide semiconductor is turned ON according to the first control voltage, and the semiconductor device provides the voltage of the first node to the second node.

4. The semiconductor device of claim 3, wherein when the voltage of the first node does not exceed the voltage of the second node, the metal-oxide semiconductor is turned OFF according to the first control voltage, and the semiconductor device electrically isolates the first node from the second node.

5. The semiconductor device of claim 1, further comprising:
a semiconductor substrate, having a first conductivity type;
a buried layer, having a second conductivity type;
a first well, having the second conductivity type and formed on the buried layer;
a second well, having the second conductivity type and formed on the buried layer; and
a third well, having the first conductivity type, formed on the buried layer, and deposited between the first well and the second well.

6. The semiconductor device of claim 5, further comprising:
a first doping region, having the second conductivity type and formed in the first well;
a second doping region, having the second conductivity type and formed in the second well, wherein the second doping region is electrically coupled to the first doping region;
a third doping region, having the second conductivity type and formed in the third well; and
a fourth doping region, having the first conductivity type and formed in the third well.

7. The semiconductor device of claim 6, wherein the third doping region, the fourth doping region, and the third well form the diode.

8. The semiconductor device of claim 6, wherein the third doping region forms the cathode node of the diode, and the first doping region, the second doping region, and the fourth doping region form the anode node of the diode.

9. The semiconductor device of claim 6, wherein the first well, the second well, and the buried layer are configured to lower a leakage current that flows from the fourth doping region to the semiconductor substrate through the third well.

10. The semiconductor device of claim 6, further comprising:
a fourth well, having the first conductivity type and formed in the semiconductor substrate; and
a fifth doping region, having the second conductivity type and formed in the fourth well.

11. The semiconductor device of claim 10, further comprising:
a fifth well, having the second conductivity type and formed in the fourth well;
a sixth doping region, having the second conductivity type and formed in the fifth well; and
a gate structure, formed in the fourth well and deposited between the fifth doping region and the sixth doping region, and on the fifth well.

12. The semiconductor device of claim 11, wherein the gate structure, the fifth doping region, and the sixth doping region respectively form the first gate terminal, the first source/drain terminal, and the second source/drain terminal of the metal-oxide semiconductor.

13. The semiconductor device of claim 12, wherein the fifth doping region is electrically coupled to the third doping region and the gate structure receives the first control voltage.

14. The semiconductor device of claim 12, further comprising:
a sixth well, having the second conductivity type and formed in the semiconductor substrate;
a seventh doping region, having the second conductivity type and formed in the sixth well; and
an eighth doping region, having the second conductivity type and formed in the sixth well.

15. The semiconductor device of claim 14, further comprising:
a seventh well, having the first conductivity type, formed in the sixth well, and deposited between the seventh doping region and the eighth doping region; and
a ninth doping region, having the first conductivity type and formed in the seventh well.

16. The semiconductor device of claim 15, wherein the seventh doping region, the eighth doping region, and the ninth doping region form the junction field-effect transistor, wherein the seventh doping region forms the third source/drain terminal, the eighth doping region forms the fourth source/drain terminal, and the ninth doping region forms the second gate terminal.

17. The semiconductor device of claim 15, wherein the seventh doping region is electrically coupled to the sixth doping region, the eighth doping region is electrically coupled to the second node, and the ninth doping region receives the second control voltage.

18. The semiconductor device of claim 15, wherein there is a predetermined distance between the eighth doping region and the ninth doping region, wherein the predetermined distance determines a maximum voltage of the second node.

19. The semiconductor device of claim 15, wherein the first doping region, the fourth doping region, the third doping region, the second doping region, the fifth doping region, the sixth doping region, the seventh doping region, the ninth doping region, and the eighth doping region are formed as a concentric structure.

20. The semiconductor device of claim 15, wherein the first conductivity type is P-type and the second conductivity type is N-type.
